(19) United States
(12) Patent Application Publication
(10) Pub. No.: US 2009/0166795 A1
(43) Pub. Date: Jul. 2, 2009

(54) SCHOTTKY DIODE OF SEMICONDUCTOR DEVICE AND METHOD FOR MANUFACTURING THE SAME

(76) Inventor: Chul-Jin Yoon, Suwon-si (KR)

Correspondence Address: SHERR & VAUGHN, PLLC, 620 HERNDON PARKWAY, SUITE 200, HERNDON, VA, 20170, US

(21) Appl. No.: 12/344,535

(22) Filed: Dec. 28, 2008

(30) Foreign Application Priority Data
Dec. 28, 2007 (KR) 10-2007-0139707

(51) Int. Cl. H01L 29/47; H01L 21/28

(52) U.S. Cl. 257/474; 438/582; 257/E29.148; 257/E21.158; 438/424

(57) ABSTRACT

A method includes forming a first conductive type buried layer on a semiconductor substrate, forming a second conductive type epi-layer on the semiconductor substrate using an epitaxial growth method such that the epi-layer surrounds the buried layer, forming a first conductive type plug from the surface of the semiconductor substrate to the buried layer, forming a first conductive type well, which is horizontally spaced from the first conductive type plug, from the surface of the semiconductor substrate to the buried layer, and forming a plurality of metal contacts as an anode and cathode of the schottky diode, respectively, by making electrical connection to the well and plug.

The present application claims priority under 35 U.S.C. 119 to Korean Patent Application No. 10-2007-0139707 (filed on Dec. 28, 2007), which is hereby incorporated by reference in its entirety.

### BACKGROUND

In general, a threshold voltage of a diode can vary depending on the substance of the diode. For example, when a diode is made of silicon (Si), its threshold voltage is about 0.6 to 0.7 V. In this case, there exists a recovery time during which current flows for some time even after powering off due to minority carriers remaining inside the diode.

A schottky barrier diode is a diode using a semiconductor and metal junction, and its threshold voltage is about half that of a typical diode. For example, a threshold voltage of a schottky diode is about 0.4 to 0.5 V. Further, in the case of the schottky diode, current flows by majority carriers instead of minority carriers. Therefore, the schottky diode has an advantage that a reverse recovery time is very short, since there is no accumulation effect. Due to this advantage, the schottky diode is widely used for high current and high-speed rectification in addition to low voltage applications.

However, one disadvantage of a schottky diode is that leakage current is relatively high and an internal pressure is relatively low. In this regard, the schottky is used for relatively low voltage and high current rectifier applications. The schottky diode is used as a rectifier in the high frequency region. This requires characteristics that show high current even with a high reverse breakdown voltage and predetermined forward voltage. In the case of the schottky diode, a breakdown voltage is low as a result of high leakage current at reverse bias. Such a disadvantage prevents the schottky diode from being used as a high power diode which requires a high breakdown voltage. To compensate for this problem, a schottky diode having a structure of SiC and metal junction, in which the metal uses SiC instead of silicon as a semiconductor, is used. Further, a guardring method is used.

FIG. 1 is a sectional view illustrating a related schottky diode of a semiconductor device. Referring to FIG. 1, an N+ buried layer 12 is formed on a P type epi-layer 10, and an N type well is widely formed horizontally over the buried layer 12. Inside the well 14, a plurality of P type guardrings 17 and a plurality of P type ion injection regions 16 which serve as a pick up terminal are formed. An oxide layer 18 is formed on the overall surface of the epi-layer 10, and a metal wiring 20 serving as an anode of the schottky diode is formed passing through the oxide layer 18. Further, metal wirings 22 and 24 serving as a cathode of the schottky diode is formed passing through the oxide layer 18.

However, the related schottky diode has a structure wherein a P type guardring 17 is formed inside the overall formed N type substances 12, 14, and 16. Therefore, the related schottky diode still has a reverse breakdown voltage that is low.

### SUMMARY

Embodiments relate to a schottky diode of a semiconductor device having a high reverse breakdown voltage and a method for manufacturing the same. Embodiments relate to a method for manufacturing a schottky diode of a semiconductor device that includes forming a first conductive type buried layer on a semiconductor substrate, forming a second conductive type epi-layer on the semiconductor substrate using an epitaxial growth method such that the epi-layer surrounds the buried layer, forming a first conductive type plug from the surface of the semiconductor substrate to the buried layer, forming a first conductive type well, which is horizontally spaced from the first conductive type plug, from the surface of the semiconductor substrate to the buried layer, and forming a plurality of metal contacts as an anode and cathode of the schottky diode, respectively, by making electrical connection to the well and plug.

Embodiments relate to a schottky diode of a semiconductor device that includes a first conductive type buried layer formed inside a semiconductor substrate, a second conductive type epi-layer formed inside the semiconductor substrate such that the epi-layer surrounds the buried layer, a first conductive type plug formed from the surface of the semiconductor substrate to the buried layer, a first conductive type well, which is horizontally spaced from the first conductive type plug, formed from the semiconductor substrate to the buried layer, and a plurality of metal contacts formed as an anode and cathode of the schottky diode, respectively, by making electrical connection to the well and plug.

Embodiments relate to a schottky diode of a semiconductor device and its manufacturing method of in which a well is formed to the defined area where the schottky diode actually operates. As a result, by replacing the guardring, which is a space between the plug and well, with a low concentrated P type epi-layer, the schottky diode exhibits high reverse breakdown voltage with having only the well and the epi-layer, which is a P type doped layer.

### DRAWINGS

FIG. 1 is a sectional view illustrating a related schottky diode of a semiconductor device.

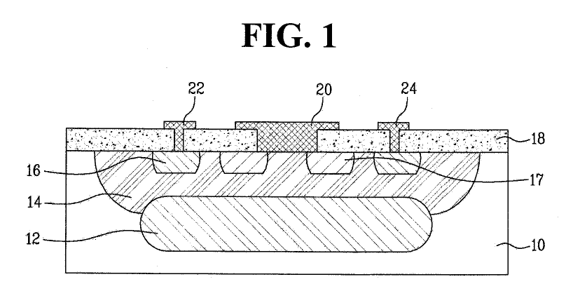

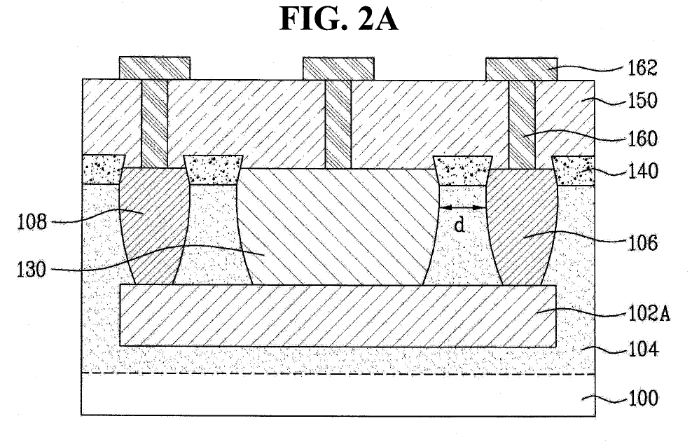

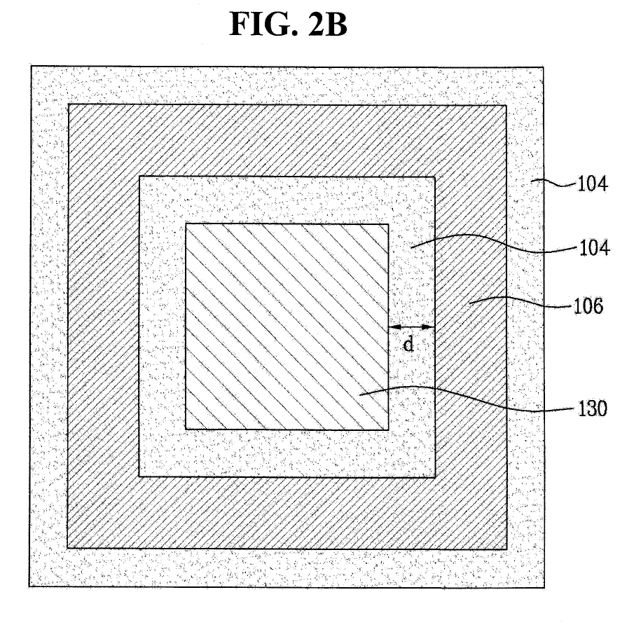

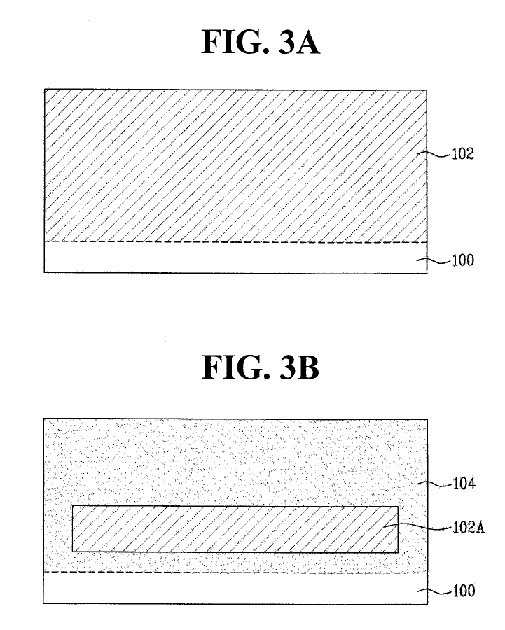

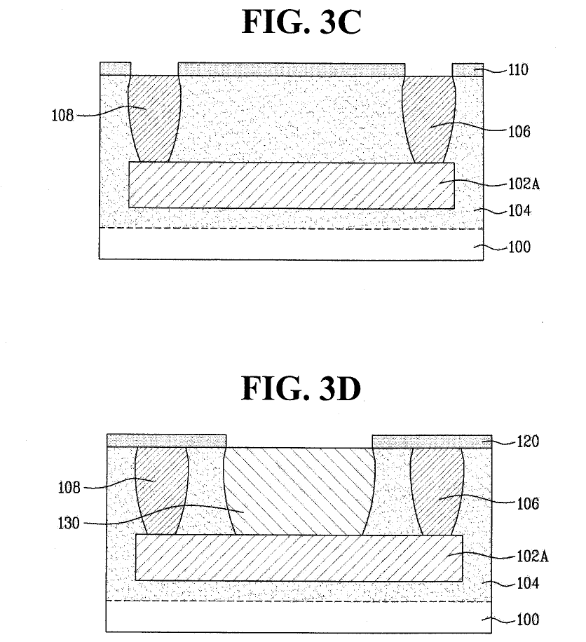

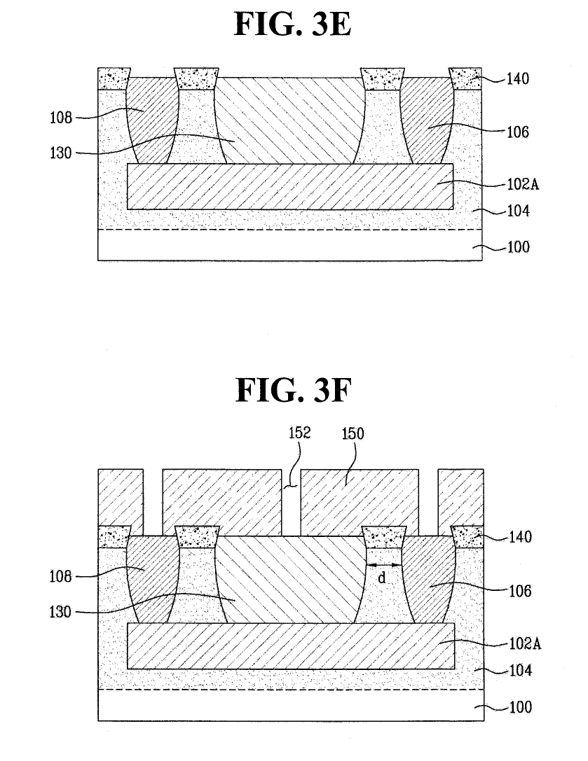

Example FIGS. 2A and 2B are views each illustrating a schottky diode of a semiconductor device according to embodiments.

Example FIGS. 3A to 3F are sectional views illustrating a method for manufacturing a schottky diode of a semiconductor device according to embodiments.

### DESCRIPTION

Reference will now be made in detail to a schottky diode of a semiconductor device according to embodiments, examples of which are illustrated in the accompanying drawings. Example FIGS. 2A and 2B are views each illustrating a schottky diode of a semiconductor device according to embodiments. Example FIG. 2A is a sectional view illustrating the schottky diode and example FIG. 2B is a plan view illustrating the schottky diode.

First, a first conductive type buried layer 102A may be formed inside a semiconductor substrate 100, and a second conductive type epi-layer 104 may be formed inside the semiconductor substrate 100 such that the epi-layer 104 surrounds the buried layer 102A. For example, the first conductive type may be an N type, and the second conductive type may be a P type.

First conductive type plugs 106 and 108 may be vertically formed from the surface of the semiconductor substrate 100 to the buried layer 102A. A first conductive type well 130, which is horizontally spaced from the first conductive type plugs 106 and 108, may be vertically formed from the surface of the semiconductor substrate 100 to the buried layer 102A. As shown in example FIG. 2B, the plug 106 may be formed such that it surrounds the well 130. The well 130 may be an active region where the schottky operation is actually carried out.

According to embodiments, a horizontal distance d between the plug 106 or 108 and the well 130 may be designed depending on a desired breakdown voltage of a schottky diode. Typically, the longer the horizontal distance d, the higher the breakdown voltage of the schottky diode. A device isolation layer 140 may be formed on, or over, the semiconductor substrate 100, between the plugs 106 and 108 and the well 130. The device isolation layer 140, as shown in example FIG. 2A, may be formed into a shallow trench isolation layer. On the other hand, the device isolation layer 140 may be formed into a LOCOS type, unlike the isolation layer shown in example FIG. 2A.

A plurality of metal contacts 160 may be formed inside an insulating layer 150 so that the metal contacts may each make electrical connection to the well 130 and the plugs 106 and 108. The metal contact 160 may, for example, be made of tungsten. A metal wiring 162 may be formed on top of, or over, each metal contact 160. The metal wiring 162 connected to the well 130 through the metal contact 160 may correspond to the anode of the schottky diode. The metal wiring 162 connected to the plugs 106 and 108 through the metal contact 160 may correspond to the cathode of the schottky diode.

Hereinafter, the method for manufacturing a schottky diode of a semiconductor device according to embodiments will be described with reference to the appended drawings. Example FIGS. 3A to 3F are sectional views illustrating a method for manufacturing a schottky diode of a semiconductor device according to embodiments.

Referring to example FIG. 3A, a first conductive type buried layer 102 may be formed on, or over, a semiconductor substrate 100. The buried layer 102 may be formed on the semiconductor substrate 100, for example, by ion injection. When the first conductive type is an N type, for example, the N+ buried layer 102 can be formed by ion injecting highly concentrated N type (N+) impurities into the semiconductor substrate 100. Referring to example FIG. 3B, a second conductive type epi-layer 104 may be formed on, or over, the semiconductor substrate 100 by an epitaxial growth method such that the epi-layer 104 surrounds the buried layer 102. As a result of forming the epi-layer 104, the buried layer 102A exists underneath the epi-layer 104.

Referring to example FIG. 3C, first conductive type plugs 106 and 108 may be vertically formed from approximately the surface of the semiconductor substrate 100 to approximately the buried layer 102A. When the first conductive type is an N type, the plugs 106 and 108 can be formed, for example, by ion injecting the highly concentrated N type (N+) impurities. According to embodiments, the plugs 106 and 108 may be formed by forming an ion injection mask 110 for opening a region where the plugs are to be formed on, or over, the epi-layer 104, and then selectively ion injecting the impurities into the epi-layer 104 using the ion injection mask 110. After forming the plugs 106 and 108, the ion injection mask 110 may be removed.

Referring to example FIG. 3D, a first conductive type well 130, which may be horizontally spaced from the first conductive type plugs 106 and 108, may be vertically formed from approximately the surface of the semiconductor substrate 100 to approximately the buried layer 102A. The well 130 may, for example, be formed by forming an ion injection mask 120 for opening a region where the well is to be formed on, or over, the overall surface of the semiconductor 100, and then ion injecting the impurities into the semiconductor substrate 100 using the ion injection mask 120.

A horizontal distance d between the plug 106 or 108 and the well 130 may be determined depending on a width of the opening of the ion injection mask 120. Therefore, the opening width of the ion injection mask 120 may be adjusted so as to meet the breakdown voltage of the schottky diode. For example, when the opening width of the ion injection mask 120 is increased, a reverse breakdown voltage of the schottky diode may be reduced. When the opening width of the ion injection mask 120 is decreased, a reverse breakdown voltage of the schottky diode may be increased. After forming the well 130, the ion injection mask 120 may be removed.

Referring to example FIG. 3E, a device isolation layer 140 may be formed between the plugs 106 and 108 and the well 130. When forming the device isolation layer 140 into an STI layer, trenches may be formed on, or over, the semiconductor substrate inbetween the plugs 106 and 108 and the well 130. Thereafter, an insulating substance such as a field oxide may be buried into the trenches to form the device isolation layer 140. Then, a plurality of metal contacts 160 may be formed to make electrical connection to the well 130 and the plugs 106 and 108.

Referring to example FIG. 3F, an insulating layer 150 may be formed on, or over, substantially the overall surface of the semiconductor substrate 100 including the device isolation layer 140. Thereafter, a space where each metal contact 160 is to be formed may be removed from the insulating layer, for example, by using a photolithography and etching process to form a plurality of via holes 152. A metal substance such as, for example, tungsten may be buried into the via holes 152 to form the metal contacts 160. After forming the metal contacts, as shown in example FIG. 2A, a metal wiring 162 may be formed on top of each metal contact 160. A variety of different processes for forming the metal contacts 160 and metal wirings 160 may be utilized, according to embodiments.

The schottky diode according to embodiments adopts a structure that may connect the highly concentrated N type (N+) plugs 106 and 108 and the active region 130 vertically to the N type buried layer 102A. This structure may, for example, be used for the bipolar junction transistor (BJT) during a bipolar-CMOS-DMOS process.

It will be obvious and apparent to those skilled in the art that various modifications and variations can be made in the embodiments disclosed. Thus, it is intended that the disclosed embodiments cover the obvious and apparent the modifications and variations, provided that they are within the scope of the appended claims and their equivalents.

What is claimed is:

1. A method for manufacturing a schottky diode of a semiconductor device comprising:
forming a first conductive type buried layer over a semiconductor substrate;
forming a second conductive type epi-layer over the semiconductor substrate such that the epi-layer substantially surrounds the buried layer;
forming a first conductive type plug from approximately a surface of the semiconductor substrate to approximately the buried layer;
forming a first conductive type well, which is horizontally spaced from the first conductive type plug, from approximately the surface of the semiconductor substrate to approximately the buried layer; and
forming a first electrical connection to the first conductive type well and a second electrical connection to the first conductive type plug.

2. The method according to claim 1, wherein forming the first and second electrical connections includes forming respective metal contacts.

3. The method according to claim 2, wherein each of the metal contacts comprises tungsten.

4. The method according to claim 1, wherein the first electrical connection is an anode of the schottky diode and the second electrical connection is a cathode of the schottky diode.

5. The method according to claim 1, wherein the first conductive type is an N type and the second conductive type is a P type.

6. The method according to claim 1, wherein forming the second conductive type epi-layer includes using an epitaxial growth method.

7. The method according to claim 1, wherein a horizontal distance between the first conductive type plug and the first conductive type well is selected to determine a breakdown voltage of the schottky diode.

8. The method according to claim 1, comprising:
forming a device isolation layer between the first conductive type plug and the first conductive type well.

9. The method according to claim 8, wherein forming the device isolation layer includes:
forming a trench on the semiconductor substrate between the first conductive type plug and the first conductive type well; and
burying the trench with an insulating substance.

10. The method according to claim 1, wherein the first conductive type buried layer is formed underneath the second conductive type epi-layer.

11. The method according to claim 1, wherein forming the first conductive type plug comprises:
forming an ion injection mask for exposing the region where the plug is to be formed, over the second conductive type epi-layer;
forming the first conductive type plug over the second conductive type epi-layer using the ion injection mask; and
removing the ion injection mask.

12. The method according to claim 1, comprising:
adjusting a horizontal distance between the first conductive type plug and the first conductive type well depending on a breakdown voltage of the schottky diode, after forming the first conductive type well.

13. The method according to claim 1, wherein the first conductive type plug is formed such that the plug substantially surrounds the first conductive type well.

14. A schottky diode of a semiconductor device comprising:
a first conductive type buried layer formed inside a semiconductor substrate;
a second conductive type epi-layer formed inside the semiconductor substrate such that the epi-layer surrounds the buried layer;
a first conductive type plug formed from approximately the surface of the semiconductor substrate to approximately the first conductive type buried layer;
a first conductive type well, which is horizontally spaced from the first conductive type plug, formed from approximately the semiconductor substrate to approximately the buried layer; and
a first and a second metal contact electrically coupled with the first conductive type well and the first conductive type plug, respectively.

15. The schottky diode according to claim 14, wherein the first conductive type is an N type and the second conductive type is a P type.

16. The schottky diode according to claim 14, wherein a horizontal distance between the first conductive type plug and the first conductive type well is selected to determine a breakdown voltage of the schottky diode.

17. The schottky diode according to claim 14, include a device isolation layer formed on the semiconductor substrate between the first conductive type plug and the first conductive type well.

18. The schottky diode according to claim 14, wherein the first conductive type plug substantially surrounds the first conductive type well.

19. The schottky diode according to claim 14, the first and second metal contacts are configured as the anode and cathode of the schottky diode.

20. The schottky diode according to claim 14, wherein each of the first and second metal contacts comprise tungsten.
